(19) United States
(12) Patent Application Publication
(10) Pub. No.: US 2015/0017753 A1
(43) Pub. Date: Jan. 15, 2015

(54) THIN FILM DEPOSITION APPARATUS AND MANUFACTURING METHOD OF ORGANIC LIGHT EMITTING DIODE DISPLAY USING THE SAME

(71) Applicant: Samsung Display Co., Ltd., Yongin-city (KR)

(72) Inventors: Sung-Soo Bae, Yongin-City (KR); Jae-Yong Lee, Yongin-City (KR)

(73) Assignee: Samsung Display Co., Ltd., Yongin-city (KR)

(21) Appl. No.: 14/171,023

(22) Filed: Feb. 3, 2014

(30) Foreign Application Priority Data
Jul. 9, 2013 (KR) 10-2013-0080548

(51) Int. Cl. H01L 51/56

(52) U.S. Cl. CPC H01L 51/56
USPC 438/46; 118/720

(57) ABSTRACT

The example embodiments provide a thin film deposition apparatus for deposition of an organic material having a low volatility characteristic, and a method for manufacturing an OLED display using the same. A thin film deposition apparatus includes a crucible assembly evaporating an organic material toward a substrate, and a pattern mask provided in one side of the substrate facing the crucible assembly. The crucible assembly includes a crucible coupled with the heater and containing an organic material therein, and a guide pipe coupled to an entrance of the crucible and forming an inner space extended in one direction toward the substrate from the entrance of the crucible.

### CROSS REFERENCE TO RELATED APPLICATION

This application claims priority to and the benefit of Korean Patent Application No. 10-2013-0080548 filed in the Korean Intellectual Property Office on Jul. 9, 2013, which is hereby incorporated by reference for all purposes as if fully set forth herein.

### BACKGROUND

1. Field

Exemplary embodiments of the present invention relate to a thin film deposition apparatus. Particularly, exemplary embodiments of the present invention relate to a thin film deposition apparatus appropriate for deposition of an organic material having low volatility, and a method for manufacturing an organic light emitting diode (OLED) display using the same.

2. Discussion of the Background

An organic light emitting diode (OLED) display includes a pixel circuit and an organic light emitting diode in each of a plurality of pixels. The OLED display displays an image by combining light emitted from a plurality of organic light emitting diodes. Organic light emitting diodes typically include a pixel electrode, an emission layer, and a common electrode, an intermediate layer such as an electron injection layer, an electron transport layer, a hole transport layer, and a hole injection layer. The hole injection layer is provided between the electrodes and the emission layer for high efficiency in light emission.

The emission layer and the intermediate layer may be formed using a deposition method in a vacuum chamber where a heater, a crucible, and a pattern mask are installed. The heater may be formed of a metal wire having a high resistance coefficient such as tungsten, and the heater heats the crucible using an indirect heating method by resistance heating. An organic material contained in the crucible is heated by the heater and evaporated. The evaporated organic material is passed through an opening of the pattern mask and then deposited on a substrate, such that the emission layer or the intermediate layer is formed.

A general thin film deposition apparatus provides a sufficient deposition effect with respect to organic materials exhibiting high volatility in a vacuum pressure condition. However, an organic material having low volatility in a vacuum requires a high temperature for deposition in the crucible. Therefore, parts of the heater require high heat resistance. In addition, a constant deposition rate may be obtained only by maintaining a high temperature for a specific period of time, and therefore a process time is increased and material degeneration may occur.

The above information disclosed in this Background section is only for enhancement of understanding of the background of the invention and therefore it may contain information that does not form the prior art that is already known in this country to a person of ordinary skill in the art.

### BRIEF SUMMARY OF THE INVENTION

Exemplary embodiments of the present invention provide a thin film deposition apparatus appropriate for deposition of an organic material having a low volatility characteristic, and a method for manufacturing an OLED display using the same.

In addition, exemplary embodiments provide a thin film deposition apparatus that can increase deposition efficiency of an organic material and minimize material loss during a deposition process, and a method for manufacturing an OLED display using the same.

A thin film deposition apparatus according to an exemplary embodiment includes a crucible assembly evaporating an organic material toward a substrate, and a pattern mask provided in one side of the substrate and facing the crucible assembly. The crucible assembly includes a crucible coupled with the heater and containing an organic material therein and a guide pipe coupled to an entrance of the crucible and forming an inner space extended in one direction toward the substrate from the entrance of the crucible.

A manufacturing method of an OLED display according to another exemplary embodiment includes arranging a substrate in one side of a crucible assembly, and depositing an organic material on the substrate by evaporating the organic material from the crucible assembly while moving the substrate in a first direction. The crucible assembly includes a crucible coupled with the heater and containing an organic material therein, and a guide pipe coupled to an entrance of the crucible and forming an inner space extended in one direction toward the substrate from the entrance of the crucible.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a perspective view of a thin film deposition apparatus according to a first exemplary embodiment.

FIG. 2 is a cross-sectional view of the thin film deposition apparatus according to the first exemplary embodiment.

FIG. 3 is a top plan view of an organic light emitting diode (OLED) display.

FIG. 4 is an enlarged cross-sectional view of a pixel of the OLED display.

FIG. 5 is a plan view of a porous plate of the thin film deposition apparatus of FIG. 1.

FIG. 6 is a partially enlarged cross-sectional view of a display area in FIG. 3.

FIG. 7 is a perspective view of a thin film deposition apparatus illustrating an exemplary variation of the pattern mask of FIG. 1.

FIG. 8 is a perspective view of a thin film deposition apparatus according to a second exemplary embodiment.

FIG. 9 is a cross-sectional view of the thin film deposition apparatus according to the second exemplary embodiment.

FIG. 10 is a top plan view of a porous plate of the thin film deposition apparatus of FIG. 8.

FIG. 11 is a front view of a thin film deposition apparatus according to a third exemplary embodiment.

FIG. 12 is a front view of a thin film deposition apparatus according to a fourth exemplary embodiment.

### DETAILED DESCRIPTION

The exemplary embodiments will be described more fully hereinafter with reference to the accompanying drawings, in which exemplary embodiments of the invention are shown. As those skilled in the art would realize, the described embodiments may be modified in various different ways, all without departing from the spirit or scope.

In the specification, unless explicitly described to the contrary, the word “comprise” and variations such as “comprises” or “comprising” will be understood to imply the inclusion of stated elements but not the exclusion of any other elements. In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” means positioning on or below the object portion, and does not essentially mean positioning on the upper side of the object portion based on a gravity direction.

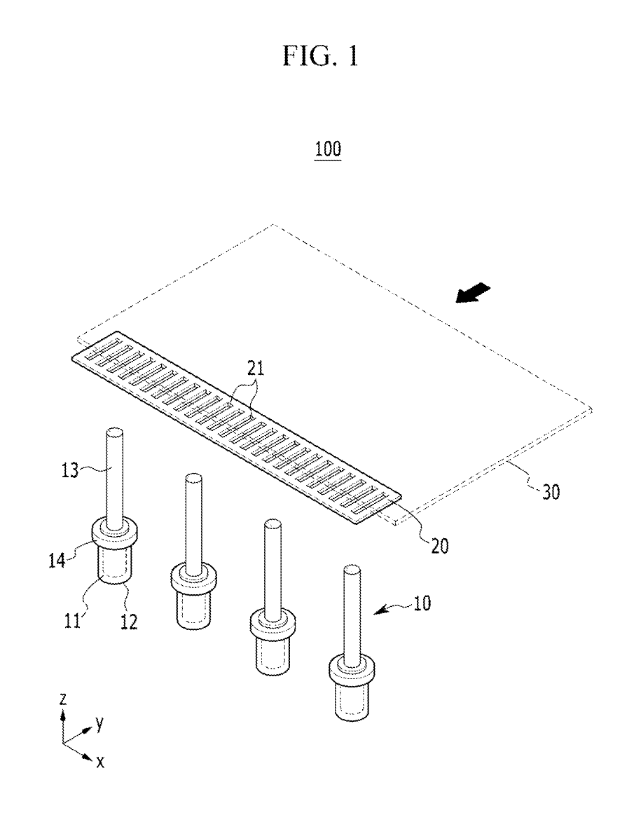

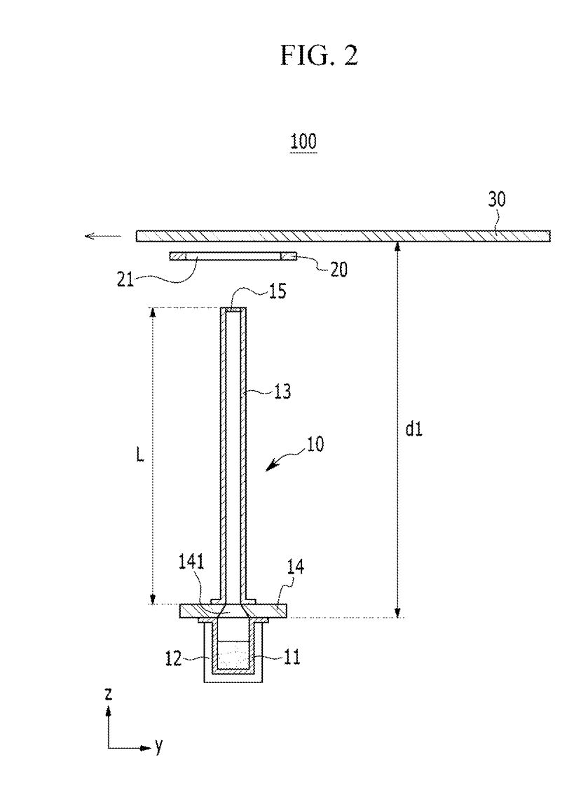

FIG. 1 and FIG. 2 are a perspective view and a cross-sectional view, respectively, of a thin film deposition apparatus according to a first exemplary embodiment.

Referring to FIG. 1 and FIG. 2, a thin film deposition apparatus 100 of the first exemplary embodiment includes at least one crucible assembly 10 and a pattern mask 20.

The crucible assembly 10 and the pattern mask 20 are provided in a chamber (not shown) where a constant vacuum may be formed. A substrate 30 is provided in an upper side in the chamber, and the at least one crucible assembly 10 is provided in a lower side in the chamber. In addition, the pattern mask 20 is positioned to one side of the substrate 30, facing the crucible assembly 10.

One crucible assembly 10 may be provided in the chamber, or a plurality of crucible assemblies 10 may be provided at a distance from each other in the chamber. FIG. 1 illustrates that a plurality of crucible assemblies 10 may be arranged in a row. The number of crucible assemblies 10 and an alignment structure of the crucible assemblies 10 are not limited to FIG. 1, and may be variously changed.

The thin film deposition apparatus 100 according to the first exemplary embodiment is provided for manufacturing an OLED display, and may be used to form an emission layer of an intermediate layer (i.e., one of an electron injection layer, an electron transport layer, a hole transport layer, and a hole injection layer) of the OLED display.

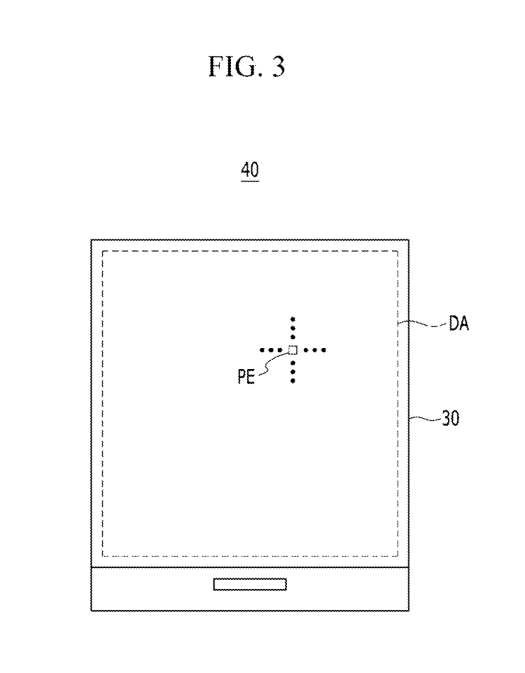

FIG. 3 is a top plan view of an OLED display manufactured using the thin film deposition apparatus of FIG. 1.

Referring to FIG. 3, an OLED display 40 includes the substrate 30 and a display area DA formed on the substrate 30. The display area DA may include a plurality of pixels PE, wherein a pixel circuit and an organic light emitting diode are formed in each pixel PE. In the display area DA, an image may be displayed with combinations of light emitted from the plurality of pixels PE.

Portions excluding the display area DA in the substrate 30 include a circuit area including a data driver and a scan driver, and a pad area where pad electrodes are formed. The pad electrodes receive control signals from an external element and transmit the received signals to the data driver and the scan driver, and the data driver and the scan driver provide signals for pixel driving to pixel circuits formed in the display area DA.

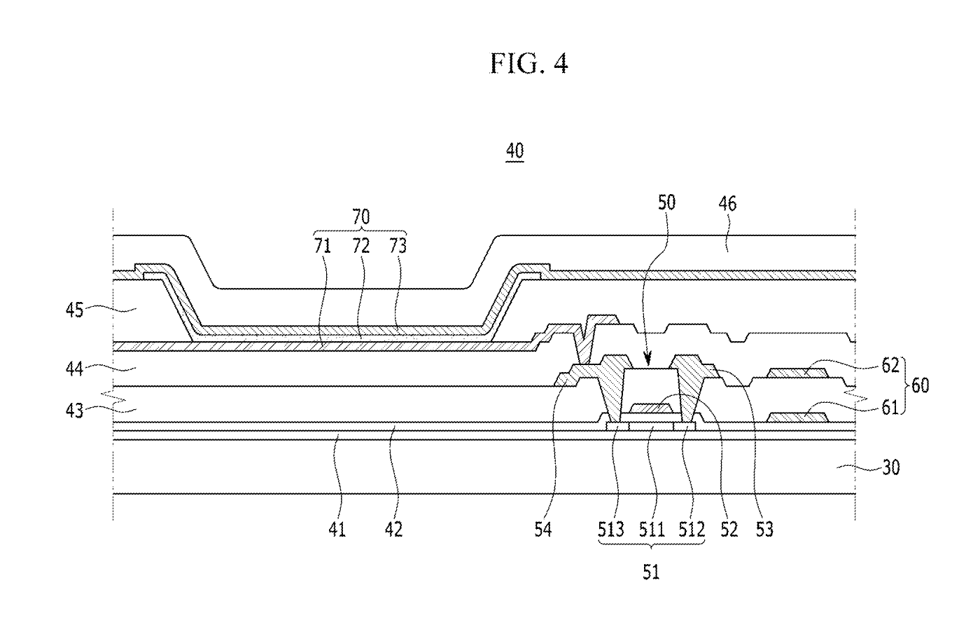

FIG. 4 is an enlarged cross-sectional view of a pixel in the OLED display of FIG. 3.

Referring to FIG. 4, a buffer layer 41, a thin film transistor 50, a capacitor 60, and an organic light emitting diode 70 are provided on the substrate 30. The thin film transistor 50 and the capacitor 60 form a pixel circuit.

The substrate 30 may be a rigid substrate such as glass or a flexible substrate such as a plastic film. When the OLED display is a bottom emission type and thus light emitted from the organic light emitting diode 70 is discharged through the substrate 30, the substrate 30 is made of a transparent material.

The buffer layer 41 is formed throughout the upper surface of the substrate 30, and may be formed of an inorganic layer including SiO₂ or SiNₓ. The buffer layer 41 provides a flat surface for forming a pixel circuit, and prevents permeation of moisture and oxygen into the pixel circuit and the organic light emitting diode 70.

The thin film transistor 50 and the capacitor 60 are formed on the buffer layer 41. The thin film transistor 50 includes a semiconductor layer 51, a gate electrode 52, and source/drain electrodes 53 and 54. The semiconductor layer 51 may be formed of a polysilicon or oxide semiconductor, and includes a channel area 511 in which an impurity is not doped, a source area 512, and a drain area 513. The source area 512 and the drain area 513 are respectively provided at lateral sides of the channel area 511 and are doped with impurities. When the semiconductor layer 51 is formed of an oxide semiconductor, a protection layer may be additionally provided for protection of the semiconductor layer 51.

A gate insulating layer 42 is provided between the semiconductor layer 51 and the gate electrode 52. An interlayer insulating layer 43 is provided between the gate electrode 52 and the source/drain electrodes 53 and 54. The capacitor 60 includes a first capacitor plate 61 formed on the gate insulating layer 42 and a second capacitor plate 62 formed on the interlayer insulating layer 43. The first capacitor plate 61 may be formed of the same material as the gate electrode 52, and the second capacitor plate 62 may be formed of the same material as the source/drain electrodes 53 and 54. The second capacitor plate 62 may be connected to the source electrode 53.

The thin film transistor 50 shown in FIG. 4 is a driving thin film transistor, and the pixel circuit further includes a switching thin film transistor (not shown). The switching thin film transistor is used as a switching element that selects a pixel for light emission, and the driving thin film transistor applies power the selected pixel for light emission.

A planarization layer 44 is provided above the source/drain electrodes 53 and 54 and the second capacitor plate 62. The planarization layer 44 may be made of an organic insulation material or an inorganic insulation material, or may be made of a combination of an organic material and an inorganic material. The planarization layer 44 forms a via hole that partially exposes the drain electrode 54, and the organic light emitting diode 70 is formed on the planarization layer 44.

The organic light emitting diode 70 includes a pixel electrode 71, an emission layer 72, and a common electrode 73. The pixel electrode 71 is formed in each pixel, and is electrically connected with the drain electrode 54 of the thin film transistor 50 through the via hole. The common electrode 73 is formed throughout the display area DA without distinction of pixels. A pixel defining layer 45, which partitions pixel areas, is formed above the pixel electrode 71, and the emission layer 72 is formed in an opening of the pixel defining layer 45 and, therefore, contacts the pixel electrode 71.

One of the pixel electrode 71 and the common electrode 73 is an anode which is a hole injection electrode and the other is a cathode which is an electron injection electrode. Holes injected from the anode and electrons injected from the cathode are combined in the emission layer 72 to generate excitons, and light emission is performed while the excitons discharge energy.

At least one of a hole injection layer and a hole transport layer may be provided between the anode and the emission layer 72. At least one of an electron injection layer and an electron transport layer may be provided between the emission layer 72 and the cathode. The hole injection layer, the hole transport layer, the electron injection layer, and the electron transport layer form an intermediate layer for improving luminous efficiency without distinction of pixels.

One of the pixel electrode 71 and the common electrode 73 is formed as a reflection layer and the other is formed as a semi-transmissive layer or a transparent conductive layer. Light emitted from the organic emission layer 72 is reflected by the reflection layer and passed through the semi-transmissive layer or the transparent conductive layer, and then emitted to the outside. In case of a front emission type, the pixel electrode 71 is formed as a reflective layer, and in case of a bottom emission type, the common electrode 72 is formed as a reflective layer.

An encapsulation substrate or a thin film encapsulation layer is provided above the organic light emitting diode 70. In FIG. 4, a thin film encapsulation layer 46 is exemplarily illustrated. The thin film encapsulation layer 46 seals the organic light emitting diode 70 from the external environment that contains moisture and oxygen to suppress deterioration of the organic light emitting diode 70 due to the moisture and oxygen. The thin film encapsulation layer is formed in a configuration in which a plurality of organic layers and a plurality of inorganic layers are alternately stacked one by one.

Referring to FIG. 1 and FIG. 2, the crucible assembly 10 includes a crucible 11 containing an organic material therein, a heater 12 heating the crucible 11, and a guide pipe 13 coupled to an entrance of the crucible 11. The crucible assembly 10 may evaporate an organic material for forming an emission layer or may evaporate an organic material for forming an intermediate layer.

The crucible 11 may be made of alumina or graphite, and the heater 12 may be formed of a resistance heating wire surrounding the external side of the crucible 11. A method of the crucible 11 and a structure of the heater 12 are not limited to the above-stated examples, and can be variously modified.

The heater 12 heats the crucible 11 to evaporate the organic material in the crucible 11. In this case, the entrance of the crucible 11 is not opened directly toward the substrate 30 but is connected with the inside of the guide pipe 13. Therefore, the organic material evaporated in the crucible 11 moves along the inside of the guide pipe 13 and is then dispersed toward the substrate 30 from the entrance of the guide pipe 13 rather than being scattered.

The guide pipe 13 has an inner space extended in one direction toward the substrate 30 from the entrance of the crucible 11. That is, the guide pipe 13 may be formed in a shape of a cylinder extended in one direction without having a bent portion. The guide pipe 13 may be disposed perpendicular to the base of the entrance of the crucible 11, and an inner diameter of the guide pipe 13 may be smaller than the diameter of the entrance of the crucible 11. The guide pipe 13 may have a quadrangular or polygonal cross-sectional shape instead of the cylindrical shape.

In addition, an adaptor 14 that functions as a joint connection may be provided between the entrance of the crucible 11 and the guide pipe 13. The adapter 14 is mechanically coupled to each of the crucible 11 and the guide pipe 13 for combination of the crucible 11 and the guide pipe 13, and forms a funnel-shaped opening 141 to connect the entrance of the crucible 11 and the inner space of the guide pipe 13. The adapter 14 may be fastened to each of the guide pipe 13 and the entrance of the crucible 11 by a fastening member (not shown) such as a bolt.

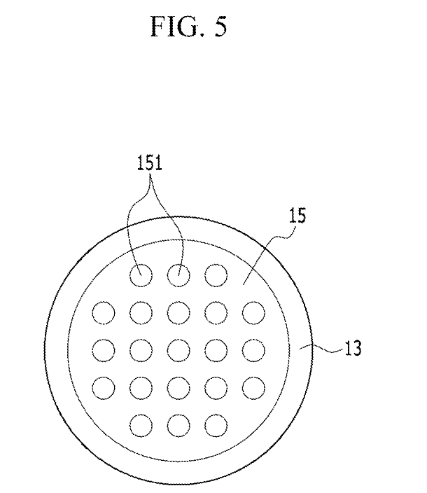

The guide pipe 13 forms a path for the movement of the organic material evaporated in the crucible 11 to in a straight line in one direction, and at the same time disposes points from which the organic material is dispersed toward the substrate 30 to be closer to the substrate 30. In this case, a porous plate 15 (refer to FIG. 5) having a plurality of entrances 151 is formed in an end of the entrance of the guide pipe 13, facing the substrate 30 to maintain uniform flow of the organic material.

In addition, a sensor (not shown) may be provided midway between the porous plate 15 and the pattern mask 20. The sensor detects the amount of organic material evaporated from the crucible assembly 10, and a controller (not shown) may control a temperature of the crucible 11 based on a signal detected by the sensor.

When the guide pipe 13 is not provided, the organic material is widely dispersed toward the substrate 30 from the entrance of the crucible 11. However, in the first exemplary embodiment, the organic material moves in a straight line along the inner space of the guide pipe 13 and is then dispersed toward the substrate 30 from the entrance of the guide pipe 13. In the first exemplary embodiment, a dispersion angle and a deposition area of the organic material are smaller than a case in which the guide pipe 13 is not provided.

The crucible assembly 10 of the first exemplary embodiment is appropriate for deposition of an organic material having low volatility. Low volatility implies that a deposition rate is low under the same temperature condition so that a significant amount of time is consumed in deposition to a desired thickness. When the guide pipe 13 is not provided, the organic material is widely dispersed from the entrance of the crucible 11, thereby causing significant material loss and a significantly long period of time for deposition.

However, in the first exemplary embodiment, the evaporated organic material is gathered in the inner space of the guide pipe 13 and moves in a straight line along the inner space of the guide pipe 13, and is then dispersed within a narrow range toward the substrate 30 from the entrance of the guide pipe 13. Therefore, the thin film deposition apparatus 100 according to the first exemplary embodiment can minimize material loss of the organic material having a low volatility characteristic and improve deposition efficiency by shortening the deposition time.

In this case, a length L (refer to FIG. 2) of the guide pipe 13 may be set to be 0.2 times to 0.8 times a distance d1 (refer to FIG. 2) between the entrance of the crucible 11 and the substrate 30. When the length L of the guide pipe 13 is less than 0.2 times the distance d1 between the entrance of the crucible 11 and the substrate 30, the efficiency provided by the guide pipe 13 is decreased and the organic material discharged from the guide pipe 13 is widely dispersed, thereby causing material loss. On the contrary, when the length L of the guide pipe 13 exceeds 0.8 times the distance d1 between the entrance of the crucible 11 and the substrate 30, the organic material exceeds a monitoring range of the sensor so that the sensor cannot measure the amount of evaporation.

Meanwhile, a deposition area of the organic material with respect to the substrate 30 may be decreased in one crucible assembly 10 due to the guide pipe 13, but a plurality of crucible assemblies 10 are disposed parallel with each other at a distance from each in a lower portion of the substrate 30 so that the deposition area of the organic material with respect to the substrate 30 can be increased.

The pattern mask 20 has at least one pattern opening 21. When the crucible assembly 10 evaporates the organic material for forming the emission layer, the pattern mask 20 has a plurality of pattern openings 21 corresponding to a pixel column of a specific color. In addition, the substrate 30 may be moved in one direction by a transfer apparatus (not shown) during a deposition process.

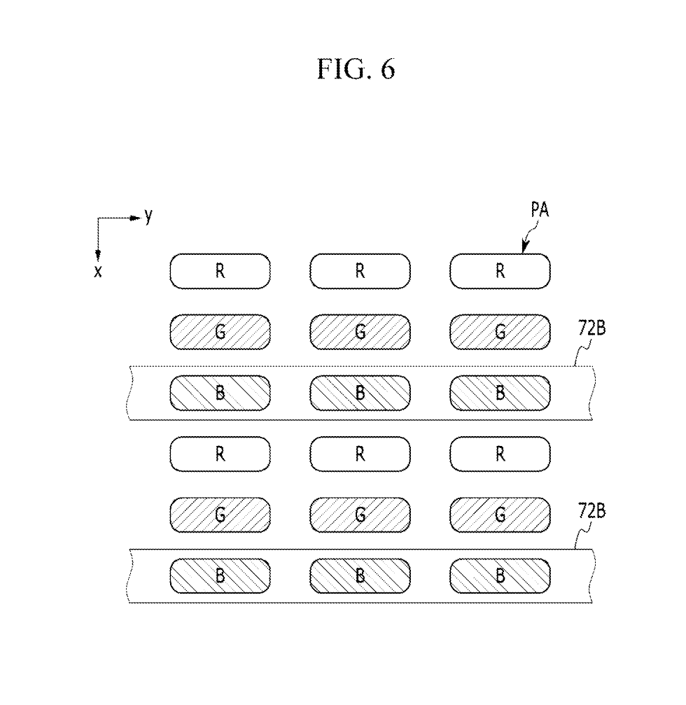

FIG. 6 is a partially enlarged view of the display area of FIG. 3.

Referring to FIG. 6, each pixel area PA partitioned by the pixel defining layer 45 may include a red pixel area R, a green pixel area G, and a blue pixel area B. Pixel areas PA of the same color are disposed in parallel with each other along a first direction (y-axis direction) on the substrate 30, and pixel areas PA of different colors are alternately disposed along a second direction (x-axis direction) that crosses the first direction.

Referring to FIG. 1 and FIG. 2, the pattern mask 20 forms slit-shaped pattern openings 21 that are parallel with the first direction (y-axis direction). The respective pattern opening 21 correspond to pixel areas of specific colors, and the length of the pattern mask 20 along the second direction (x-axis direction) may be the same as the width of the display area DA along the second direction. Therefore, the organic material evaporated in the crucible assembly 10 is passed through the pattern openings 21 of the pattern mask 20 and then deposited on the substrate 30 such that an emission layer 72 of a specific color is formed.

In this case, the length of the pattern mask 20 along the first direction is smaller than the width of the display area DA along the first direction, and the substrate 30 moves along the first direction during the deposition process. Accordingly, the emission layer 72 is continuously and uniformly deposited on the substrate 30 along the first direction. In FIG. 6, reference numeral 72B denotes a blue emission layer deposited using the above-stated method.

As described, as the substrate 30 is moved relative to the thin film deposition apparatus 100, deposition of the emission layer 72 is performed using a scanning method. Therefore, the pattern mask 20 of the thin film deposition apparatus 100 according to the first exemplary embodiment can be easily manufactured by reducing the size of the pattern mask 20.

That is, a conventional pattern mask has a size that corresponds to the display area DA, but in the first exemplary embodiment, the length of the pattern mask 20 along the first direction may be formed to be smaller than the width of the display area DA along the first direction. Thus, handling of the pattern mask 20 can be further easily performed during all the processes for forming pattern openings by processing a metal sheet, extending the pattern mask and fixing the extended pattern mask to a frame by welding, and moving and cleaning the pattern mask.

The substrate 30 may be a mother substrate including a plurality of display areas DA. In this case, the length of the pattern mask 20 along the second direction may be the same as the width of the mother substrate. As the substrate 30 moves and deposition proceeds, the pattern mask 20 is disposed at a constant distance from the substrate 30.

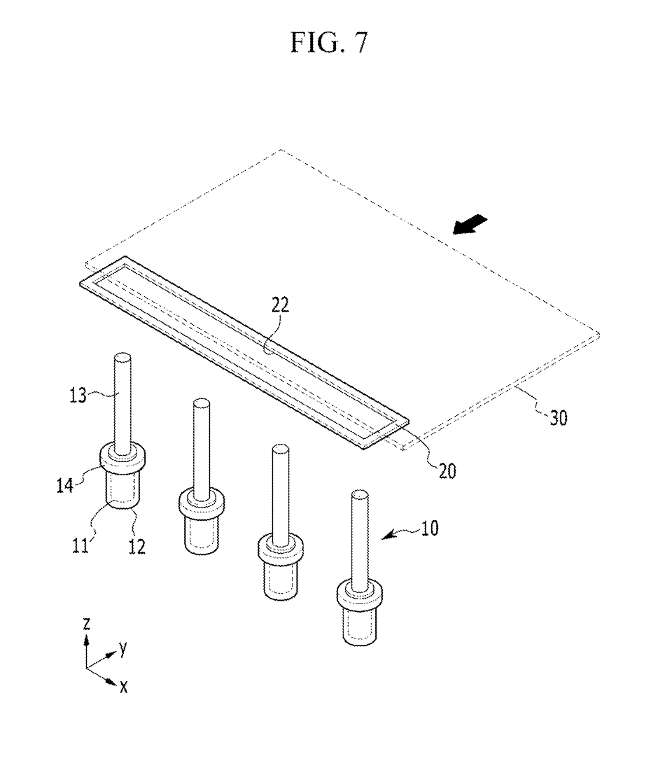

FIG. 7 is a perspective view of the thin film deposition apparatus showing an exemplary variation of the pattern mask of FIG. 1.

Referring to FIG. 7, when the crucible assembly 10 evaporates an organic material for forming an intermediate layer, the pattern mask 20 may form one pattern opening 22 that corresponds to the display area DA.

A length of the pattern opening 22 along a first direction (y-axis direction) is smaller than a width of the display area DA along the first direction, and a length of the pattern opening 22 along a second direction (x-axis direction) may be equal to a width of the display area DA along the second direction. In addition, during a deposition process, the substrate 30 moves along the first direction and, thus, deposition of the intermediate layer is performed using a scanning method.

Meanwhile, rather than forming the intermediate layer throughout the display area DA, a forming material and a deposition thickness of the intermediate layer may be set to be different according to a color of a pixel. In this case, the intermediate layer is formed on the substrate 30 using the thin film deposition apparatus 100 shown in FIG. 1 and FIG. 2.

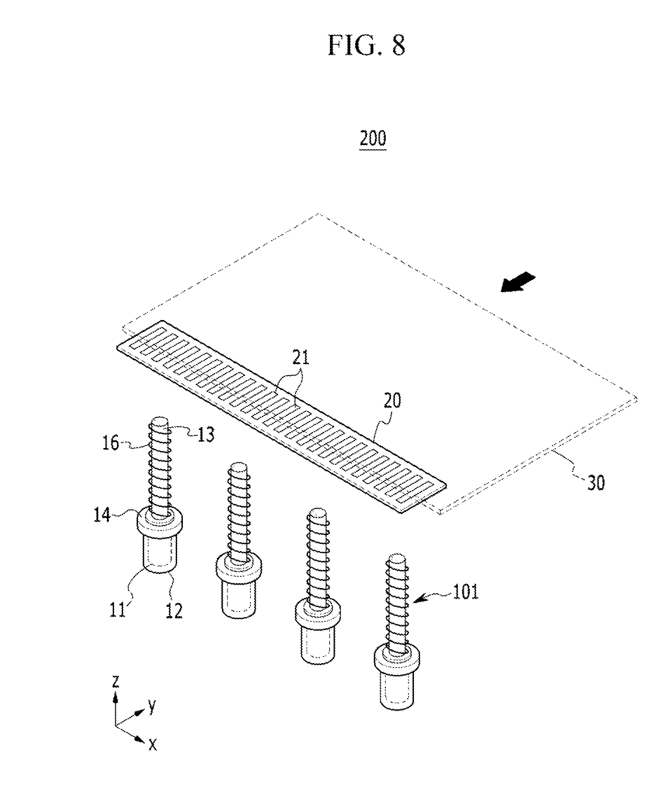

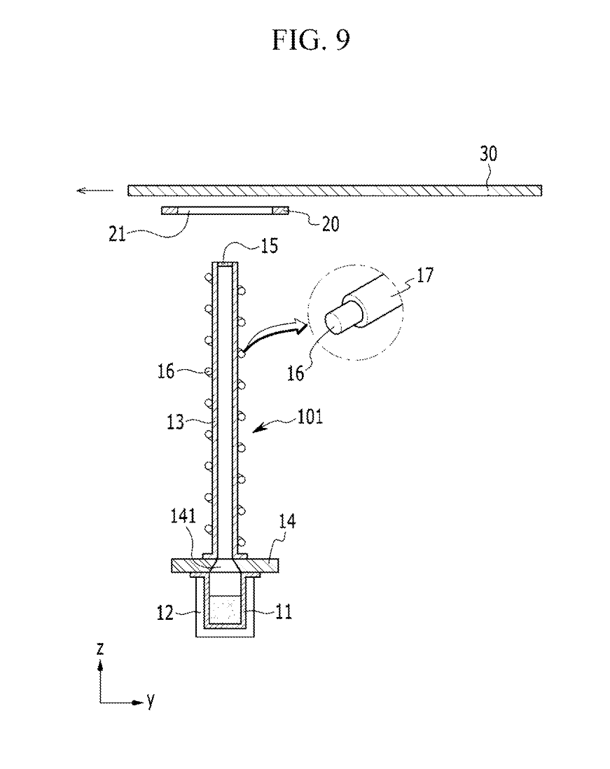

FIG. 8 and FIG. 9 are respectively a perspective view and a cross-sectional view of a thin film deposition apparatus according to a second exemplary embodiment.

Referring to FIG. 8 and FIG. 9, a thin film deposition apparatus 200 according to the second exemplary embodiment is similar to the thin film deposition apparatus of the first exemplary embodiment in structure, except that a resistance heating wire 16 is additionally provided to each of crucible assemblies 101. The same reference numerals are used for the same components as those of the first exemplary embodiment.

The resistance heating wire 16 spirally surrounds a guide pipe 13 while contacting an exterior wall of the guide pipe 13. The resistance heating wire 16 is made of a metal having a high resistance coefficient such as tungsten, and is coated with an insulation layer 17 that can tolerate vacuum and heat. The insulation layer 17 may be made of a fluorine resin that does not perform outgassing in high heat, for example, polytetrafluoroethylene (PTFE) resin.

Lateral ends of the resistance heating wire 16 are fixed to an adapter 14, and are connected with an external power device (not shown) to receive power for heating.

In case of an organic material requiring a high deposition temperature, the organic material evaporated in the crucible 11 is deposited on an interior wall of the guide pipe 13 while passing through the guide pipe 13, and eventually the guide pipe 13 may be blocked. In the second exemplary embodiment, the resistance heating wire 16 prevents the organic material evaporated from the crucible 11 from blocking the guide pipe 13 by heating it.

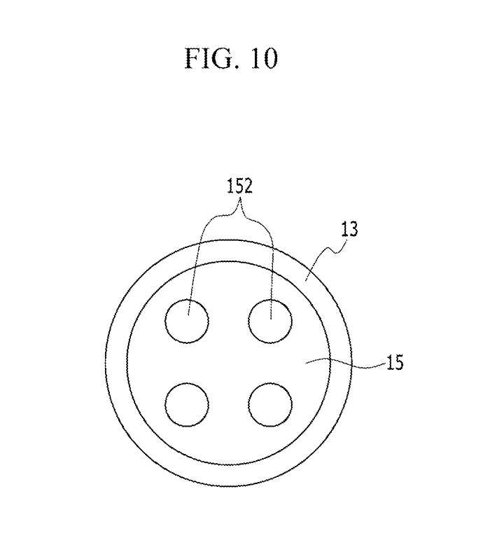

Therefore, the thin film deposition apparatus 200 according to the second exemplary embodiment can be usefully applied for deposition of an organic material that has a low volatility and requires a high deposition temperature. Meanwhile, a porous plate 15 (refer to FIG. 10) provided at an end of an entrance side of the guide pipe 13 may have a plurality of entrances 152. Here, the plurality of entrances may be larger than the entrances of the porous plate of the first exemplary embodiment, and the number of entrances formed in the porous plate 15 of the second exemplary embodiment may be less than the number of entrances formed in the porous plate 15 of the first exemplary embodiment.

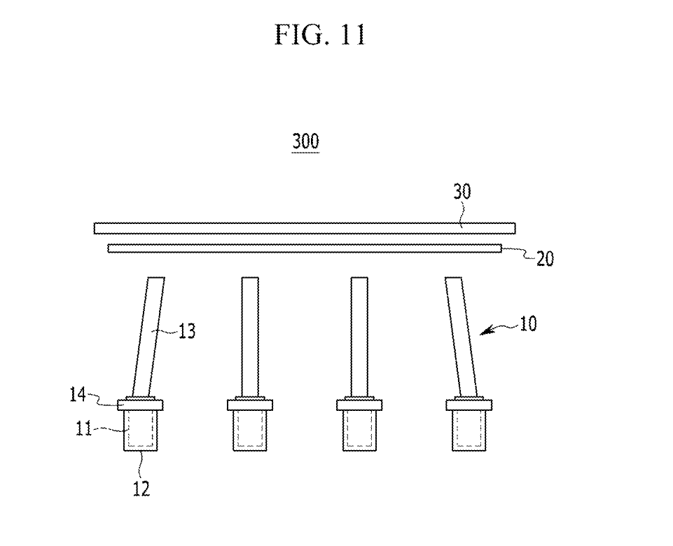

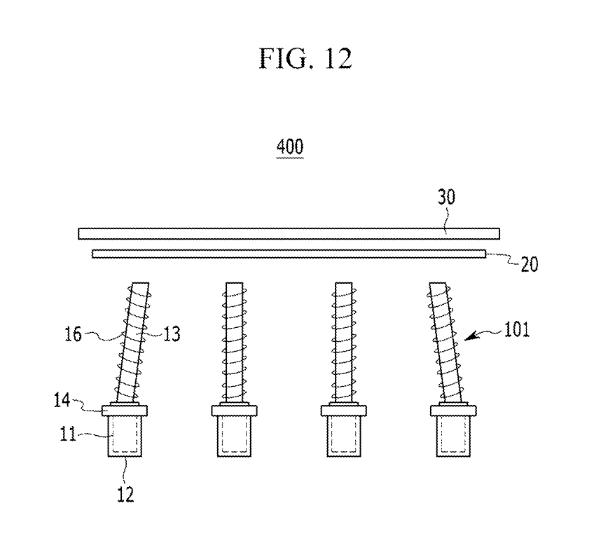

FIG. 11 and FIG. 12 are front views of thin film deposition apparatuses according to third and fourth exemplary embodiments.

Referring to FIG. 11, a thin film deposition apparatus 300 according to the third exemplary embodiment is the same as the thin film deposition apparatus of the first exemplary embodiment, except that a guide pipe 13 is disposed with a slope with respect to an entrance of a crucible 11 in at least one crucible assembly 10. The same reference numerals are used for the same components as those of the first exemplary embodiment.

Referring to FIG. 12, a thin film deposition apparatus 400 of the fourth exemplary embodiment is the same as the thin film deposition apparatus of the second exemplary embodiment, except that a guide pipe 13 is disposed with a slope with respect to an entrance of a crucible 11 in at least one crucible assembly 10. The same reference numerals are used for the same components as those of the second exemplary embodiment.

In the third exemplary embodiment and the fourth exemplary embodiment, the guide pipe 13 is fixed to an adapter 14 while being inclined with a constant angle with respect to the entrance of the crucible 11. The guide pipe 13 may be inclined toward the center of a substrate or a specific area of the substrate, and an inclination angle and an inclination direction of the guide pipe 13 may be varied according to installation locations of the crucible assemblies 10 and 101. Therefore, deposition of an emission layer or an intermediate layer can be uniform in both of the center portion and the outer portions of the substrate 30.

FIG. 11 and FIG. 12 illustrate that the guide pipe 13 are inclined toward the center portion of the substrate 30 with respect to the crucible assemblies 10 and 101 disposed corresponding to the outer sides of the substrate 30. However, an inclination angle and an inclination direction of the guide pipe 13 may be modified in various ways.

In the above-described first to fourth exemplary embodiments, the thin film deposition apparatuses 100, 200, 300, and 400 are respectively provided with the guide pipes 13 so that movement of an organic material having a low volatility characteristic can be maintained to be straight in deposition of the organic material. Thus, the deposition temperature and the deposition speed of the organic material can be constantly maintained even in an area close to the substrate. As a result, material loss can be minimized and deposition efficiency can be improved. In addition, in case of the second and fourth exemplary embodiment, a constant deposition rate can be maintained while preventing the guide pipe 13 from being blocked.

Next, a deposition experiment result of an organic material using the thin film deposition apparatus of the first and second exemplary embodiments and a thin film deposition apparatus of a comparative example will be described. A thin film deposition apparatus of a comparative example is the same as the thin film deposition apparatus of the above-stated first exemplary embodiment, except that a guide pipe and an adapter are omitted.

First, an experiment for deposition of a blue emission layer using the thin film deposition apparatus of the first exemplary embodiment and the thin film deposition apparatus of the comparative example was performed. The blue emission layer has a low deposition temperature and a low volatility characteristic. Table 1 shows an initial deposition temperature, a final deposition temperature, a deposition standby time consumed to reach a final deposition speed, and variation in weight of a material in a crucible after 1000 Å deposition.

TABLE 1

| | Initial | Final | | |
|---|---|---|---|---|
| | deposition | deposition | Deposition | Variation in |
| | temperature | temperature | standby time | weight |
| First | 130° C. | 170° C. | 5 minutes | 0.04 g reduced |
| exemplary | (0.05 A/s) | (1.0 A/s) | | |
| embodiment | | | | |
| Comparative | | | 10 minutes | 0.1 g reduced |
| example | | | | |

As shown in Table 1, compared to the comparative example, the deposition time was reduced by half and the amount of material loss in the crucible was reduced from 0.1 g to 0.04 g after 1000 Å deposition in the thin deposition apparatus of the first exemplary embodiment.

Next, an experiment for deposition of a hole injection layer using the thin film deposition apparatus of the second exemplary embodiment and the thin film deposition of the comparative example was performed. The hole injection layer has a high deposition temperature and a low volatility characteristic. Table 2 shows an initial deposition temperature, a final deposition temperature, a deposition standby time consumed to reach a final deposition speed, and variation in weight of a material in the crucible after 1000 Å deposition.

TABLE 2

| | Initial | Final | | |
|---|---|---|---|---|
| | deposition | deposition | Deposition | Variation in |
| | temperature | temperature | standby time | weight |
| Second | 330° C. | 350° C. | 7 minutes | 0.05 g reduced |
| exemplary | (0.05 A/s) | (1.0 A/s) | | |
| embodiment | | | | |
| Comparative | | | 15 minutes | 0.15 g reduced |
| example | | | | |

As shown in Table 2, compared to the comparative example, the deposition time was reduced by more than half and the amount of material loss in the crucible was reduced from 0.15 g to 0.05 g after 1000 Å deposition in the thin deposition apparatus of the second exemplary embodiment.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film deposition apparatus comprising:
a crucible assembly configured to evaporate an organic material toward a substrate; and a pattern mask facing the crucible assembly, wherein
the crucible assembly comprises
a crucible coupled with a heater and configured to receive an organic material therein, and
a guide pipe coupled to an entrance of the crucible and forming an inner space extended in a direction toward the substrate from the entrance of the crucible.

2. The thin film deposition apparatus of claim 1, wherein
the length of the guide pipe is 0.2 to 0.8 times a distance between the entrance of the crucible and the substrate.

3. The thin film deposition apparatus of claim 2, further comprising
a porous plate comprising a plurality of entrances disposed at an end of the guide pipe closest to the substrate.

4. The thin film deposition apparatus of claim 1, wherein
the crucible assembly further comprises
an adapter disposed between the crucible and the guide pipe and coupling the crucible with the guide pipe.

5. The thin film deposition apparatus of claim 2, wherein
the crucible assembly further comprises a resistance heating wire disposed on an external side of the guide pipe.

6. The thin film deposition apparatus of claim 5, wherein
the resistance heating wire spirally surrounds the guide pipe and is insulated by a fluorine resin layer.

7. The thin film deposition apparatus of claim 1, wherein
the guide pipe is disposed perpendicular to the entrance of the crucible.

8. The thin film deposition apparatus of claim 1, wherein
the guide pipe is disposed with a slope with respect to the entrance of the crucible.

9. The thin film deposition apparatus of claim 1, wherein
the deposition apparatus comprises a plurality of crucible assemblies disposed at a distance from each other along a direction.

10. The thin film deposition apparatus of claim 9, wherein
the plurality of crucible assemblies comprise a first crucible assembly facing a center portion of the substrate and a second crucible assembly facing an external portion of the substrate, and
the guide pipe of the first crucible assembly is disposed perpendicular to the entrance of a first crucible of the first crucible assembly and the guide pipe of the second crucible assembly is disposed with a slope with respect to the entrance of a second crucible of the second crucible assembly.

11. The thin film deposition apparatus of claim 1, wherein
the pattern mask is spaced apart from the substrate, the substrate being movable in a first direction when the crucible assembly evaporates the organic material.

12. The thin film deposition apparatus of claim 11, wherein
the substrate comprises a display area, the pattern mask forms at least one pattern opening, and
a length of the pattern mask along the first direction is smaller than a width of the display area along the first direction.

13. The thin film deposition apparatus of claim 12, wherein
the disposition apparatus comprises a plurality of crucible assemblies disposed at a distance from each other along a second direction that crosses the first direction.

14. A manufacturing method of an organic light emitting diode (OLED) display, comprising:
arranging a substrate at a side of a crucible assembly; and
depositing an organic material on the substrate by evaporating the organic material from the crucible assembly while moving the substrate in a first direction, wherein
the crucible assembly comprises
a crucible coupled with a heater, the crucible containing an organic material therein, and
a guide pipe coupled to an entrance of the crucible and forming an inner space extended in a direction toward the substrate from the entrance of the crucible.

15. The manufacturing method of claim 14, wherein
a pattern mask having a plurality of pattern openings formed therein is disposed at a side of the substrate and facing the crucible assembly, and
each of the pattern openings is formed in the shape of a slit that is parallel with the first direction.

16. The manufacturing method of claim 15, wherein
the substrate comprises a display area, and
a length of the pattern mask along the first direction is smaller than a width of the display area along the first direction.

17. The manufacturing method of claim 16, wherein
the crucible assembly is configured to evaporate an organic material for forming an emission layer, and
the organic material evaporated in the crucible assembly is continuously deposited on the substrate along the first direction.

18. The manufacturing method of claim 14, wherein
a pattern mask having one pattern opening formed therein is disposed at a side of the substrate and facing the crucible assembly.

19. The manufacturing method of claim 18, wherein
the substrate comprises a display area, and
a length of the pattern mask along the first direction is smaller than a width of the display area along the first direction.

20. The manufacturing method of claim 19, wherein
the crucible assembly is configured to evaporate an organic material for forming an intermediate layer, and
the organic material evaporated in the crucible assembly is continuously deposited on the substrate along the first direction.
